(19) United States
(12) Patent Application Publication
(10) Pub. No.: US 2023/0343640 A1
(43) Pub. Date: Oct. 26, 2023

(54) METHOD FOR FORMING CONDUCTIVE FEATURE

(71) Applicant: TAIWAN SEMICONDUCTOR MANUFACTURING COMPANY LTD., Hsinchu (TW)

(72) Inventors: KUAN WEI SU, TAINAN CITY (TW); CHE-LI LIN, KAOHSIUNG CITY (TW); LING-SUNG WANG, TAINAN CITY (TW); LI-YI CHEN, TAINAN CITY (TW)

(21) Appl. No.: 17/725,439

(22) Filed: Apr. 20, 2022

(51) Int. Cl. H01L 21/768; H01L 23/522

(52) U.S. Cl. CPC H01L 21/7684; H01L 21/76834; H01L 23/5226; H01L 21/76808; H01L 21/76816; H01L 21/76843

(57) ABSTRACT

A method for forming a conductive feature includes following operations. A first insulating layer is formed over a substrate. The first insulating layer is patterned to form a first recess in the first insulating layer. The first recess is filled with a conductive material. A plurality of second recesses are formed in the conductive material. Each of the second recesses overlaps the first recess. A portion of the conductive material is removed to form a first conductive feature. A ratio of a sum of opening areas of the second recesses to an opening area of the first recess is less than 1%.

### BACKGROUND

Integrated circuits are manufactured by forming discrete semiconductor devices in surfaces of silicon wafers. A multi-level metallurgical interconnection network is then formed over the devices, contacting their active elements, and wiring them together to create desired circuits. The circuits are then further interconnected by utilizing additional conductive features over additional insulating layers with conductive vias passing through the insulating layers. Thus, conductive features providing the interconnection may be referred to as an interconnection structure or a back-end-of-line (BEOL) interconnection. In addition, depending upon complexity of the entire integrated circuit, several levels of wiring interconnections are used. On an uppermost level, the wiring is terminated at a conductive feature such as a pad structure, to which a chip’s external wiring connections are bonded. Additionally, the pad structure may also serve as a probe pad.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flowchart representing a method for forming a bonding pad structure according to aspects of the present disclosure.

FIGS. 2 to 11, 13A and 13B are cross-sectional views illustrating a pad structure at various fabrication stages according to aspects of the present disclosure in one or more embodiments.

FIGS. 12A to 12F are top views of a portion of a conductive material over one recess.

FIGS. 14 to 26B are cross-sectional views illustrating an interconnect level at various fabrication stages according to aspects of the present disclosure in one or more embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first.” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially.” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Conductive features, which are used to form back-end-of line (BEOL) metallic interconnect structure or used to serve as probe pads or bonding pads, are formed by patterning an insulating layer to form openings, filling the openings with conductive materials, and removing superfluous conductive materials to form a level of the interconnect structure and a pad structure. In some embodiments, the removal of the superfluous conductive material is performed by a polishing back operation. For example, a chemical mechanical polishing (CMP) operation is used.

It is found that when the conductive feature has a large polishing area, a dishing issue may arise. That is, a central region of the polished feature is dished to form a curved surface that is lower than a peripheral region of the same polished feature. The dishing issue may weaken a wiring layer of an interconnect level of the interconnect structure and the pad structure due to a thin central region. Further, a subsequently attached wire bond or a punch from a probe pin will be not only weak mechanically but also excessively resistive. In some comparative approaches, the weakening of the bonding pad structure caused by the dishing issue is reflected by high yield losses at wafer acceptance testing (WAT) and at subsequent package stress testing. Theses yield losses also forewarn a reliability degradation.

Embodiments of a method for forming a conductive feature are therefore provided. In some embodiments, the conductive feature has a plurality of recesses formed over its surface. A polishing area may be reduced due to such recesses. Further, a dishing issue may be mitigated due to the reduced polishing area of the connecting structure.

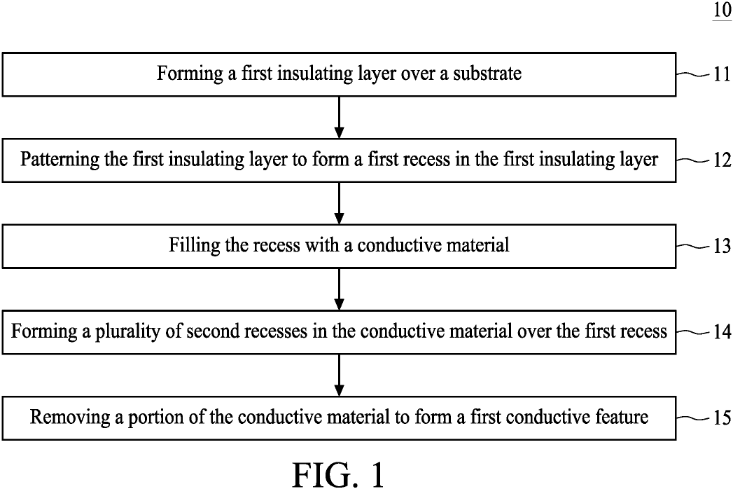

FIG. 1 is a flowchart representing a method for forming a conductive feature 10 according to aspects of the present disclosure. The method 10 includes a number of operations (11, 12. 13, 14 and 15). The method 10 will be further described according to one or more embodiments. It should be noted that the operations of the method 10 may be rearranged or otherwise modified within the scope of the various aspects. It should further be noted that additional processes may be provided before, during, and after the method 10. and that some other processes may be only briefly described herein. Thus, other implementations are possible within the scope of the various aspects described herein.

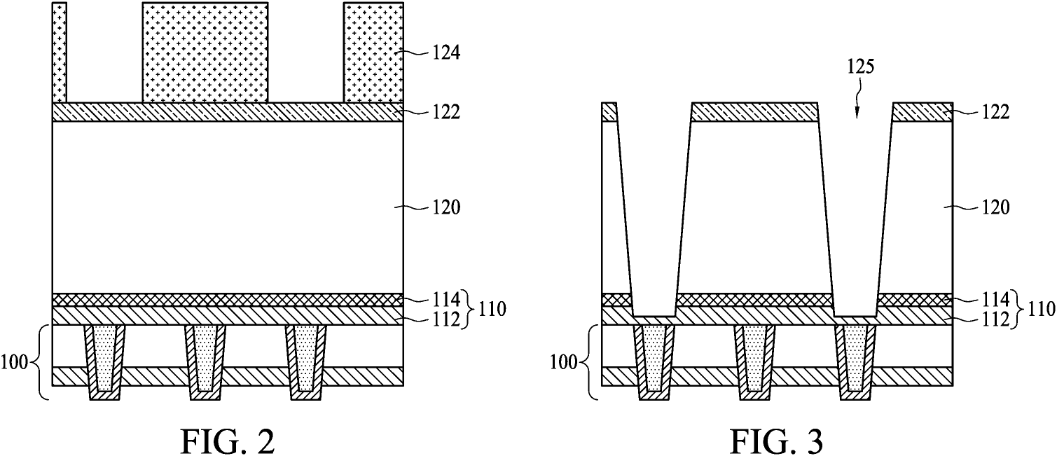

FIGS. 2 to 13B are cross-sectional views illustrating a conductive feature at various fabrication stages according to aspects of the present disclosure in one or more embodiments. In some embodiments, the conductive feature is a pad structure, such as a bonding pad structure. It should be understood that FIGS. 2 to 13B have been simplified for a better understanding of the inventive concepts of the present disclosure. Accordingly, it should be noted that additional processes may be provided before, during, and after the processes shown in FIGS. 2 to 13B, and that some other operations may only be briefly described herein.

Referring to FIG. 2, in operation 11, an insulating layer is formed over a substrate. In some embodiments, a substrate 100 is received. The substrate 100 may be a semiconductor substrate. The semiconductor substrate may include semiconductors such as germanium (Ge), silicon carbide (SiC), silicon germanium (SiGe), or diamond. Alternatively, the semiconductor substrate may include a compound semiconductor and/or an alloy semiconductor.

Isolation structures (not shown) are formed in the substrate 100. In some embodiments, the isolation structures include shallow trench isolation (STI) structures. The STI structures contain a dielectric material, which may be silicon oxide, silicon nitride, silicon oxy-nitride, fluoride-doped silicate (FSG), and/or a low-k dielectric material known in the art. The STI structures are formed by etching trenches in the substrate 100 and thereafter filling the trenches with the dielectric material. In other embodiments, deep trench isolation (DTI) structures may also be formed in place of (or in combination with) the STI structures as the isolation structures.

Integrated circuit devices (not shown) are formed in the substrate 100 using conventional state of the art process technology. The integrated circuit devices includes, for example, memory circuits, logic circuits, high frequency circuits, image sensors, and various passive and active components such as resistors, capacitors, inductors. P-channel field-effect transistors (pFET). N-channel FET (nFET), metal-oxide semiconductor field-effect transistors (MOSFET), complementary metal-oxide semiconductor (CMOS) transistors, bipolar junction transistors (BJT), laterally diffused MOS (LDMOS) transistors, high power MOS transistors, or other types of transistors.

In some embodiments, the substrate 100 include an interconnect structure. The interconnect structure includes a plurality of interconnect levels. Each interconnect level includes metal layers and vias. The interconnect levels provide interconnections (e.g., wiring) between circuitries, inputs/outputs, and various doped features formed in the substrate 100. The metal layers of interconnect levels of the interconnect structure may be referred to as M1, M2, M3, etc.. and the vias of the interconnect levels of the interconnect structure may be referred to as V1, V2. (...), Vn. In some embodiments, a metal layer in the topmost interconnect level may be referred to as Mn. The metal layer and the vias in a same interconnect level may be formed by conductive features. The conductive features may be aluminum interconnect lines or copper interconnect lines, and may include conductive materials such as aluminum, copper, aluminum alloy, copper alloy, aluminum/silicon/copper alloy, titanium, titanium nitride, tantalum, tantalum nitride, tungsten, polysilicon, metal silicide, or a combination thereof. The interconnect structure also includes an inter-metal dielectric (IMD) that provides isolation between the conductive features. The IMD may include a dielectric material such as an oxide material.

Please refer to FIG. 2,in which a substantial portion of the interconnect structure is illustrated. Only the topmost interconnect level is shown in FIG. 2, while other interconnect levels are omitted from the figures and are understood to be included in the substrate 100. As shown in FIG. 2, the topmost interconnect level may include a plurality of conductive features including the metal layers and the vias as discussed above.

A protection layer 110 can be disposed over the substrate 100. In some embodiments, the protection layer 110 may be formed of a variety of dielectric materials such as, for example, oxide (e.g., Ge oxide), nitride, oxynitride (e.g., GaP oxynitride), silicon dioxide (SiO₂), a nitrogen-bearing oxide (e.g.. nitrogen-bearing SiO₂), a nitrogen-doped oxide (e.g.. N₂-implanted SiO₂), silicon oxynitride (SiₓO_{y}N_{z}), a polymer material, or the like. In an alternative embodiment, the protection layer 110 include a polymeric material such as polyimide (PI), polybenzoxazole (PBO), benzocyclobuten (BCB), epoxy, or the like. In some embodiments, the protection layer 110 can include a lower SiN layer and an upper plasma enhanced oxide (PEOX)-undoped silicate glass (USG) (PEOX-USG) layer, but the disclosure is not limited thereto. In some embodiments, the protection layer 110 can be a multiple layer. For example, the protection layer 110 may include a first layer 112 over the substrate 100, and a second layer 114 over the firs layer 112. In some embodiments, the first layer 112 may be a silicon nitride layer, and the second layer 114 may be a silicon oxide layer (e.g., a USG) layer, but the disclosure is not limited thereto. The protection layer 110 may be formed using CVD. PVD, spin-on coating, or other suitable operation.

Still referring to FIG. 2, an insulating layer 120 is next formed over the substrate 100 and the protection layer 110. A thickness of the insulating layer 120 is greater than a thickness of the protection layer 110. In some embodiments, the insulating layer 120 is thick enough to provide an even surface. In some embodiments, the insulating layer 120 may be a multiple layer, though not shown.

In operation 12, the insulating layer 120 is patterned to form a first recess. In some embodiments, operation 12 includes further operations. For example, referring to FIGS. 2 and 3, a hard mask layer 122 and a patterned photoresist layer 124 are sequentially formed over the insulating layer 120. The patterned photoresist layer 124 includes patterns defining locations and dimensions of via openings or plug openings where conductive vias or plugs are to be formed. The patterns of the pattermed photoresist layer 124 are transferred to the hard mask layer 122. Subsequently, the insulating layer 120 is etched through the patterned hard mask layer 122 by suitable etching operations. Thus via openings 125 are formed in the insulating layer 120, as shown in FIG. 3. In some embodiments, the via openings 125 penetrate the insulating layer 120 and the protection layer 110. In such embodiments, the metal layer of the topmost interconnect level may be exposed through a bottom of the via opening 125.

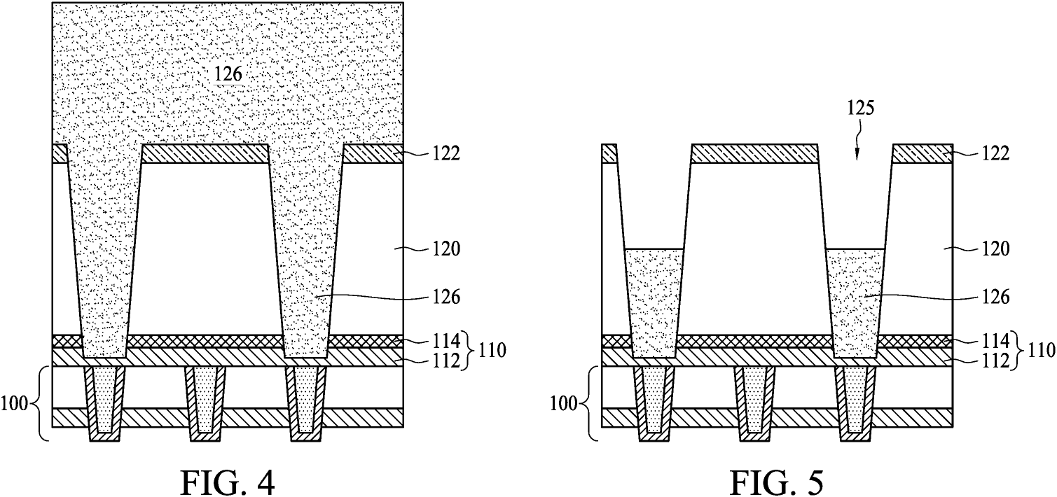

Referring to FIG. 4, in some embodiments, a sacrificial layer 126 is formed to fill the via openings 125. The sacrificial layer 126 may be a photoresist layer, but the disclosure is not limited thereto. The sacrificial layer 126 not only fills the via openings 125 but also covers a top surface of the patterned hard mask layer 122. Further, the sacrificial layer 126 is thick enough to provide a flat and even surface.

Referring to FIG. 5, in some embodiments, an etch back operation is performed. By using the etch back operation, portions of the sacrificial layer 126 are removed, and a thickness of the sacrificial layer 126 is reduced. Consequently, a top surface of the sacrificial layer 126 is lower than the top surface of the patterned hard mask layer 122 and a top surface of the insulating layer 120. However, the remaining sacrificial layer 126 still partially fills the via openings 125. Further, the metal layer of the topmost interconnect level is still covered by the remaining sacrificial layer 126, as shown in FIG. 5.

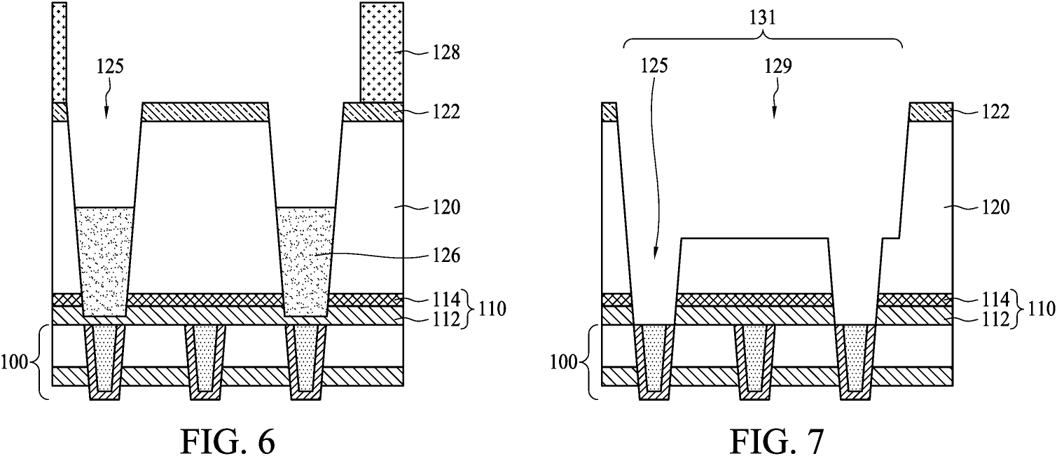

Referring to FIG. 6,in some embodiments, another patterned photoresist layer 128 is formed over the patterned hard mask layer 122. The patterned photoresist layer 128 includes patterns defining locations and dimensions of metal line openings where conductive features (i.e.. metal layers) are to be formed.

Referring to FIG. 7, in some embodiments, the pattern of the patterned photoresist layer 128 is transferred to the insulating layer 120 using a suitable etching operation. Thus, line openings 129 are formed. In some embodiments, at least one line opening 129 is coupled to the via opening(s) 125. In other words, the via opening 125 is coupled to a bottom of the line opening 129. Accordingly, a first recess 131 formed by the line opening 129 and the via opening(s) 125 is obtained in operation 12. as shown in FIG. 7. In some embodiments, after the forming of the first recess 131, the photoresist layer 128 and the sacrificial layer 126 are both removed. Thus, the metal layer of the topmost interconnect level is exposed through a bottom of the first recess 131. The metal layer of the topmost interconnect level is also exposed through the bottom of the via opening 125. In some embodiments, a dimension of the first recess 131, (i.e., a dimension of the line opening 129) is between approximately 1 µm² and approximately 1000 µm², but the disclosure is not limited thereto.

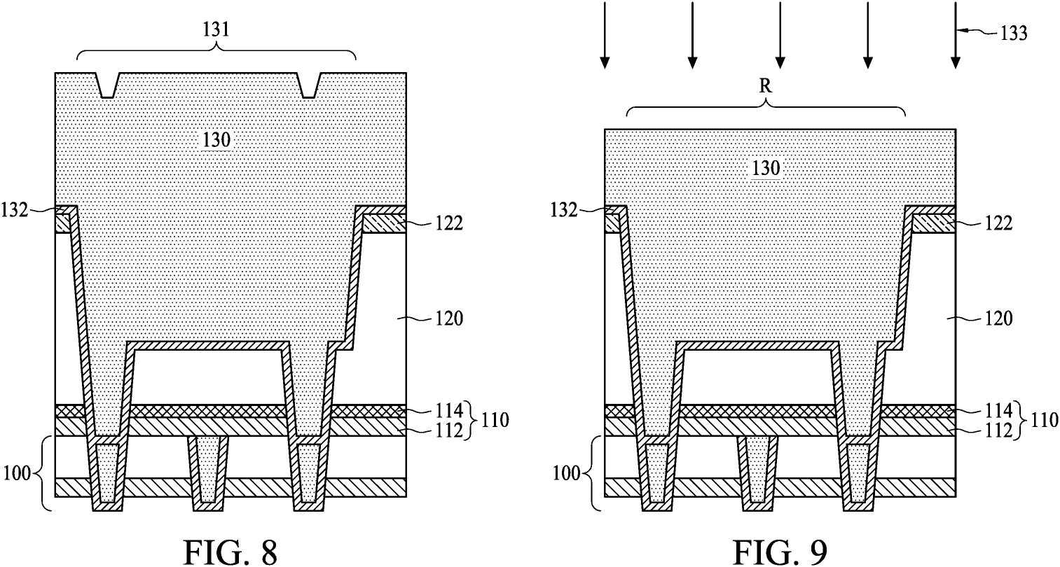

Referring to FIG. 8, in some embodiments, in operation 13, a conductive material 130 is formed to fill the first recess 131. In some embodiments, the conductive material 130 includes copper (Cu), tungsten (W), or aluminum (Al), but the disclosure is not limited thereto. The conductive material 130 not only fill the first recess 131 but also covers the top surface of the patterned hard mask layer 122. In some embodiments, a barrier layer 132 is formed between the conductive material 130 and the insulating layer 120 in order to prevent metal diffusion, but the disclosure is not limited thereto. In some embodiments, a seed layer (not shown) may be formed over the barrier layer 132 prior to the forming of the conductive material 130 in order to improve quality of the conductive material 130.

In operation 14, a plurality of second recesses are formed in the conductive material 130 in the first recess 131. In some embodiments, operation 14 includes further operations. For example, a first planarization operation, such as a first chemical-mechanical polishing (CMP) operation 133 is performed. In some embodiments, the first CMP operation 133 is used to reduce a thickness of the conductive material 130 and to obtain a substantially flat and even surface as shown in FIG. 9. In such embodiments, the top surface of the patterned hard mask layer 122 (and the barrier layer 132) is still covered by the conductive material 130 after the first CMP operation 133.

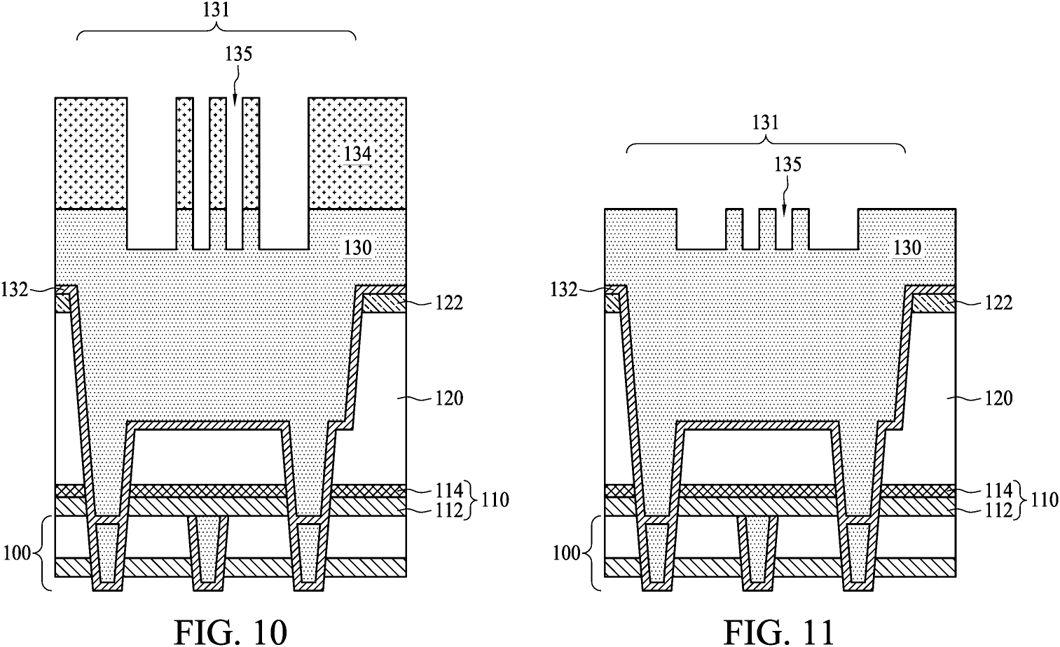

Referring to FIG. 10, in some embodiments, a patterned photoresist layer 134 is formed on the conductive material 130. The patterned photoresist layer 134 includes patterns defining locations and dimensions of a plurality of second recesses to be formed. The patterns are then transferred to the conductive material 130, and thus a plurality of second recesses 135 are formed in the conductive material 130. as shown in FIGS. 10 and 11. The patterned photoresist 134 is then removed. It should be noted that the locations of each second recess 135 is within an area where the first recess 131 is located. It may be noticed that each of the second recesses 135 overlaps the first recess 131, as shown in FIG. 11. A depth of each second recess 135 is less than a thickness of the conductive material 130, and a width or a diameter of each second recess 135 is less than a width or a diameter of the first recess 131. Further, the width or the diameter of each second recess 135 is less than a width of the line opening 129, and less than a width or a diameter of the via opening 125. In some embodiments, the width or the diameter of each second recess 135 is between approximately 0.1 micrometer and approximately 10 micrometers, but the disclosure is not limited thereto. In some embodiments, a spacing distance between two adjacent second recesses 135 is greater than approximately 1 micrometer, but the disclosure is not limited thereto. Further, a ratio of a sum of opening areas of the second recesses 135 to an opening area of the first recess 131 is less than 1%.

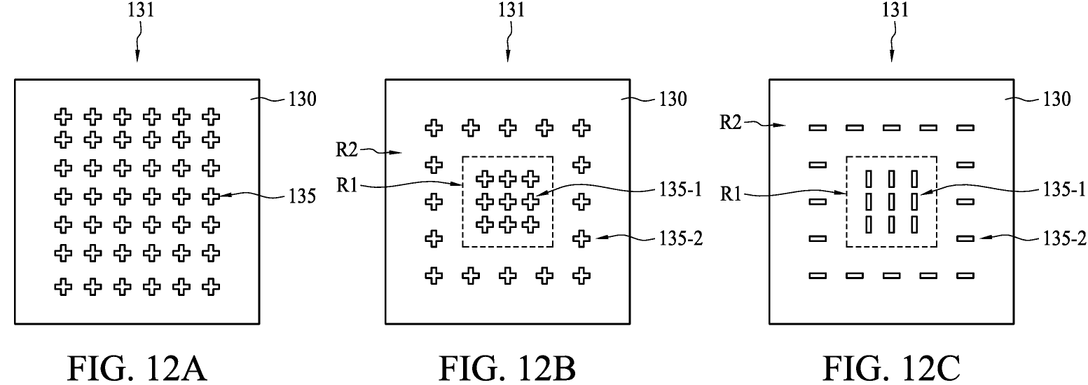

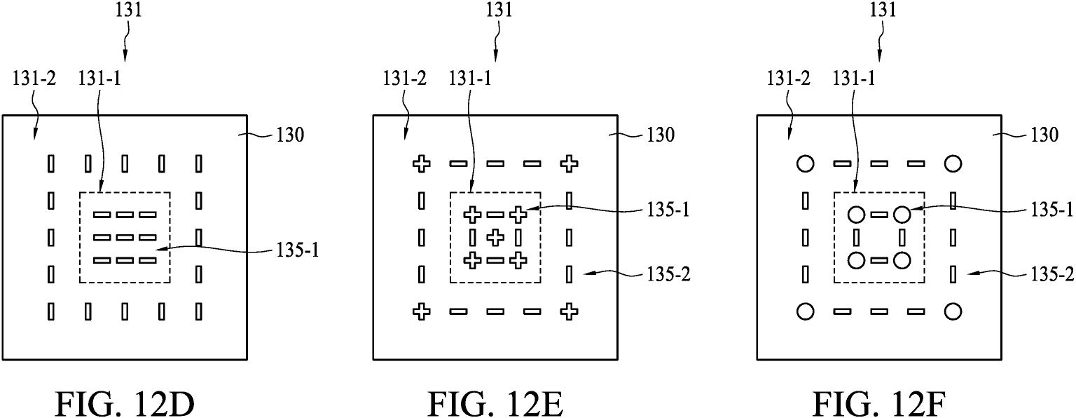

Please refer to FIGS. 12A to 12F, which are top views of a portion of the conductive material over one of the first recesses 131. In some embodiments, each of the second recesses 135 may have a similar shape. For example, each of the second recesses 135 may have a cross configuration from the top view, as shown in FIGS. 12A and 12B. The second recesses 135 may have a bar shape as shown in FIG. 12C or a circular shape as shown in FIG. 12E. In other embodiments, the second recesses 135 may have different shapes. For example, some of the second recesses 135 may have the cross shape while others may have the bar shape as shown in FIG. 12E. Some of the second recesses 135 may have the bar shape while others may have circular shape as shown in FIG. 12E.

In some embodiments, the second recesses 135 formed in the conductive material 130 may be arranged to form an array pattern, as shown in FIG. 12A. The second recesses 135 may be randomly arranged, though not shown. In some embodiments, the conductive material 130 over the first recess 131 may be defined to have a central region 131-1 and a peripheral region 131-2 surrounding the central region 131-1. In such embodiments, the second recesses 135 over the first recess 131 may be arranged and defined to a first group 135-1 located in the central region 131-1 and a second group 135-2 located in the peripheral region 131-2. Further, a recess density of the first group 135-1 is greater than a recess density of the second group 135-2. as shown in FIGS. 12B to 12E.

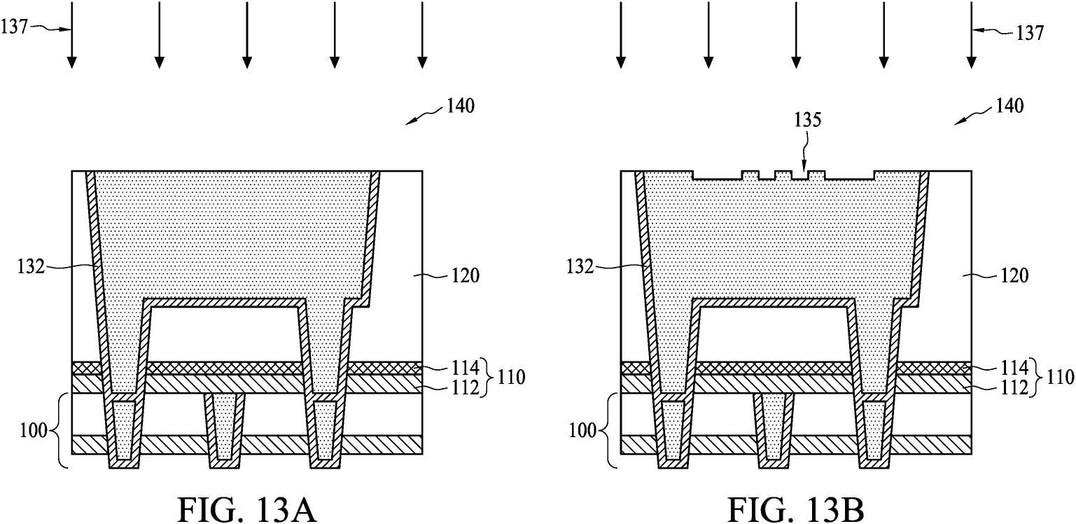

In operation 15, a portion of the conductive material 130 is removed to form a conductive feature 140. Referring to FIGS. 13A and 13B, in some embodiments, the removal is performed by a planarization operation such as a second CMP operation 137. In some comparative approaches, when there is no second recess formed in the conductive material 130 within the first recess 131, portions of the conductive material 130 suffer from a dishing issue during the CMP operation due to the large polishing area. In contrast to the comparative approaches, the second recesses 135 help reduce a polishing surface of the conductive material within the first recess 131 during the second CMP operation 137. Accordingly, the dishing issue is mitigated.

In some embodiments, a thickness of the conductive feature 140 is between approximately 100 angstroms and approximately 1000 angstroms, but the disclosure is not limited thereto.

In some embodiments, the second recesses 135 are entirely removed by the second CMP operation 137, as shown in FIG. 13A. In some embodiments, the second recesses 135 may remain in the conductive feature 140 after the second CMP 137, but the depth of each second recess 135 is reduced by the second CMP operation 137, as shown in FIG. 13B.

As mentioned above, the conductive feature 140 is used to serve as a pad structure, such as a bonding pad, in some embodiments. Therefore, a bonding structure such as a bonding wire may be formed in contact with the conductive feature 140, though not shown. It should be noted that in some embodiments when the second recesses 135 are entirely removed as shown in FIG. 13A,the bonding structure (i.e.. the bonding wire) may be directly formed on the flat surface of the conductive feature 140. In other embodiments, when the second recesses 135 remain in the conductive feature 140 as shown in FIG. 13B, the second recesses 135 may be filled with the bonding wire, though not shown.

According to the method for forming the conductive method 10, the conductive feature 140. serving as a bonding pad, is formed with the forming of the second recesses 135 interrupting the first and second CMP operations 133 and 137. The second recesses 135 help reduce the polishing area of the conductive material 130 within the first recess 131, thus the dishing issue is mitigated.

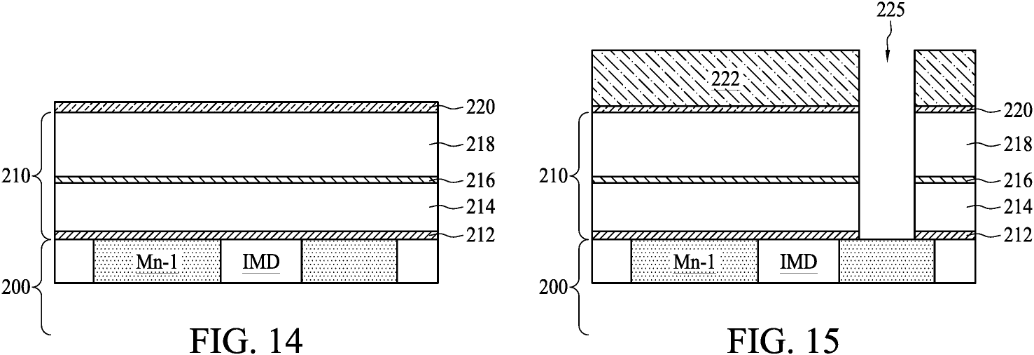

FIGS. 14 to 26B are cross-sectional views illustrating a conductive feature at various fabrication stages according to aspects of the present disclosure in one or more embodiments. In some embodiments, the conductive feature is an interconnect level of an interconnect structure. It should be understood that FIGS. 14 to 26B have been simplified for a better understanding of the inventive concepts of the present disclosure. Accordingly, it should be noted that additional processes may be provided before, during, and after the processes shown in FIGS. 14 to 26B, and that some other operations may only be briefly described herein.

Referring to FIG. 14, in operation 11, an insulating layer 210 is formed over a substrate 200. In some embodiments, the substrate 200 may be a semiconductor substrate. Materials of the semiconductor substrate may be similar to those described above and thus repeated descriptions are omitted herein. As mentioned above, isolation structures (not shown) are formed in the substrate 200. In some embodiments, the isolation structures include STI and DTI structures. Integrated circuit devices (not shown) are formed in the substrate 200 using conventional state of the art process technology.

In some embodiments, the substrate 200 includes an interconnect structure. The interconnect structure includes a plurality of interconnect levels. Each interconnect level in includes interconnected conductive layers, and each interconnected conductive layer includes metal layers and vias. The interconnect levels provide interconnections (e.g., wiring) between circuitries, inputs/outputs, and various doped features formed in the substrate 200. The metal layers of the interconnect levels of the interconnect structure may be referred to as M1, M2, M3. etc., and the vias of the interconnect levels of the interconnect structure may be referred to as V1, V2, (...). In some embodiments, a metal layer in the topmost interconnect level may be referred to as Mn. The metal layer and the vias in a same interconnect level may be formed by conductive features. Materials for forming the metal layers and the vias may be similar to those described above, and thus repeated descriptions are omitted herein. The interconnect structure also includes an inter-metal dielectric (IMD) that provides isolation between the conductive features.

Still referring to FIG. 14, FIG. 14 illustrates a substantial portion of the interconnect structure. As mentioned above, a metal layer of a topmost interconnect level of the interconnect structure may be referred to as an Mn layer, and an Mn-1 metal layer is depicted in FIG. 14. Further, the Mn-1 metal layer is embedded in an IMD layer. In some embodiments, operation 11 is performed to form an insulating layer 210 over the substrate 200, the Mn-1 metal layer and the IMD layer. In some embodiments, the insulating layer 210 may be a multiple layer including a variety of dielectric material layers. For example, the insulating layer 210 may include a first etch stop layer 212. a first dielectric layer 214, a second etch stop layer 216 and a second dielectric layer 218 sequentially stacked over the substrate 200. In some embodiments, the first dielectric layer 214 and the second dielectric layer 218 may include a similar material. For example but not limited thereto, the first and second dielectric layers 214 and 218 may include USG, but the disclosure is not limited thereto. The first etch stop layer 212 and the second etch stop layer 216 may include a similar material, but the disclosure is not limited thereto. In some embodiments, the first and second etch stop layers 212 and 216 may include different materials. For example, the first etch stop layer 212 may include silicon carbon-nitride, and the second etch stop layer 216 may include silicon nitride, but the disclosure is not limited thereto. As shown in FIG. 14, a thickness of the first and second dielectric layers 214 and 218 is greater than a thickness of the first and second etch stop layers 212 and 216. Further, a hard mask layer 220 is formed over the insulating layer 210, as shown in FIG. 14. The hard mask layer 220 may be a multiple layer or a single layer. In some embodiments, the hard mask layer 220 may include silicon oxynitride, but the disclosure is not limited thereto.

In operation 12, the insulating layer 210 is patterned to form a first recess. In some embodiments, operation 12 includes further operations. For example, referring to FIG. 15, a patterned photoresist layer 222 is formed over the hard mask layer 220. The patterned photoresist layer 222 includes patterns defining locations and dimensions of via openings or plug openings where conductive vias or plugs are to be formed. The patterns of the patterned photoresist layer 222 are transferred to the hard mask layer 220. Subsequently, the insulating layer 210 is etched through the patterned hard mask layer 220 by a suitable etching operation. Thus, via openings 225 are formed in the insulating layer 210, as shown in FIG. 15. In some embodiments, the via openings 225 penetrate the insulating layer 210. In such embodiments, the Mn-1 metal layer may be exposed through a bottom of the via opening 225. After the forming of the via opening 225, the patterned photoresist layer 222 is removed.

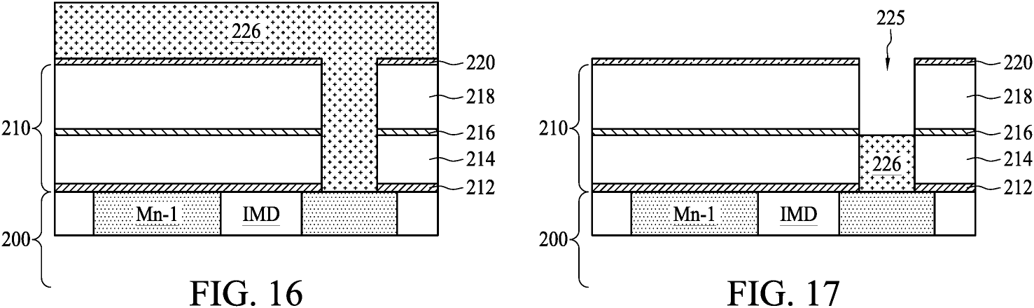

Referring to FIG. 16, in some embodiments, a sacrificial layer 226 is formed to fill the via openings 225. The sacrificial layer 226 may be a photoresist layer, but the disclosure is not limited thereto. The sacrificial layer 226 not only fills the via openings 225 but also covers a top surface of the patterned hard mask layer 220. Further, the sacrificial layer 226 is thick enough to provide a flat and even surface.

Referring to FIG. 17, in some embodiments, an etch back operation is performed. By using the etch back operation, portions of the sacrificial layer 226 are removed, and a thickness of the sacrificial layer 226 is reduced. Consequently, a top surface of the sacrificial layer 226 is lower than the top surface of the patterned hard mask layer 220 and a top surface of the insulating layer 210. However, the remaining sacrificial layer 226 still partially fills the via openings 225. Further, the Mn-1 metal layer is covered by the remaining sacrificial layer 226, as shown in FIG. 17.

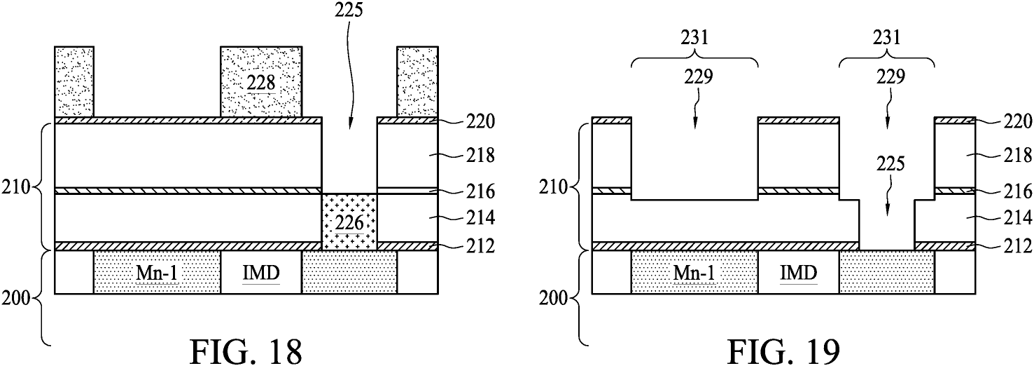

Referring to FIG. 18, in some embodiments, another patterned photoresist layer 228 is formed over the hard mask layer 220. The patterned photoresist layer 228 includes patterns defining locations and dimensions of line openings where metal layers are to be formed.

Referring to FIG. 19, in some embodiments, the patterns of the patterned photoresist layer 228 are transferred to the insulating layer 210 using a suitable etching operation. Thus, line openings 229 are formed. In some embodiments, at least one line opening 229 is coupled to the via opening 225. In such embodiments, the via opening 225 is coupled to a bottom of the line opening 229. Accordingly, a first recess 231 including the line opening 229 and the via opening 225 is obtained in operation 12. as shown in FIG. 19. In some embodiments, after the forming of the first recess 231, the patterned photoresist layer 228 and sacrificial layer 226 are both removed. Thus, the Mn-1 metal layer is exposed through the bottom of the via opening 225 of the first recess 231.

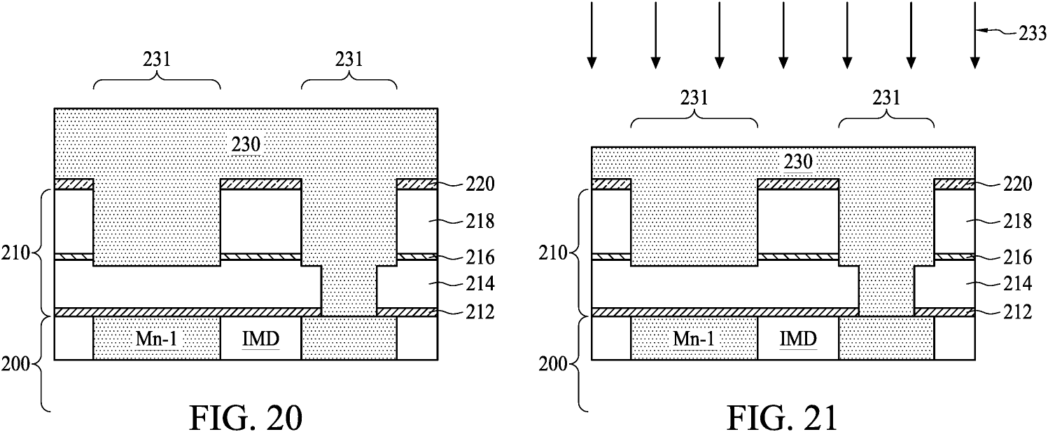

Referring to FIG. 20, in some embodiments, in operation 13, a conductive material 230 is formed to fill the first recess 231. The conductive material 230 not only fills the first recess 231. but also covers the top surface of the patterned hard mask layer 220. In some embodiments, a barrier layer (not shown) is formed between the conductive material 230 and the insulating layer 210 in order to prevent metal diffusion, but the disclosure is not limited thereto. In some embodiments, a seed layer (not shown) may be formed over the barrier layer prior to the forming of the conductive material 230 in order to improve quality of the conductive material 230.

In operation 14. a plurality of second recesses are formed in the conductive material 230 in the first recess 231. In some embodiments, operation 14 includes further operations. For example, a first planarization operation, such as a first CMP operation 233, is performed. In some embodiments, the first CMP operation 233 is used to reduce a thickness of the conductive material 230 and to obtain a substantially flat and even surface as shown in FIG. 21. In such embodiments, the top surface of the patterned hard mask layer 220 is still covered by the conductive material 230 after the first CMP operation 233.

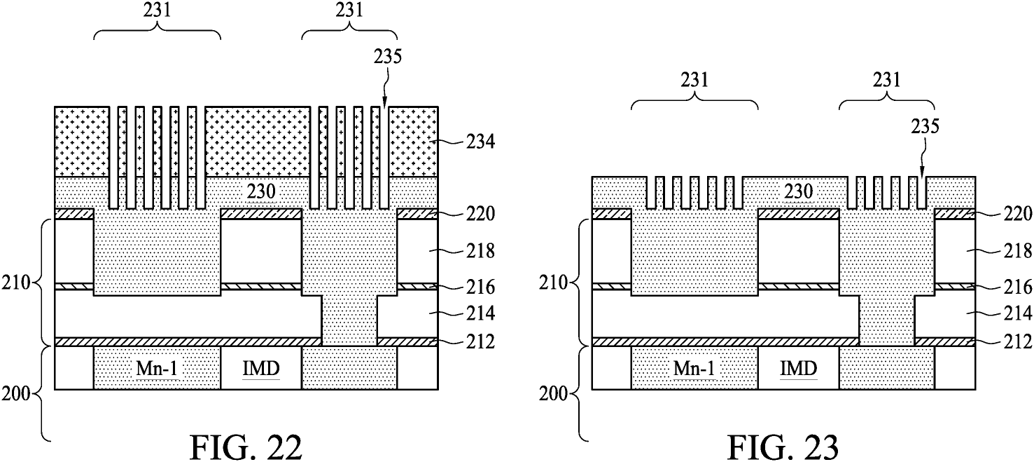

Referring to FIG. 22, in some embodiments, a patterned photoresist layer 234 is formed on the conductive material 230. The patterned photoresist layer 234 includes patterns defining locations and dimensions of a plurality of second recesses to be formed. The patterns are then transferred to the conductive material 230, and thus a plurality of second recesses 235 are formed in the conductive material 230, as shown in FIG. 22. The patterned photoresist 234 is then removed. It should be noted that the location of each second recess 235 is within an area where the first recess 231 is located. In other words, each of the second recesses 235 overlaps the first recess 231, as shown in FIG. 23. A depth of each second recess 235 is less than a thickness of the conductive material 230. and a width or a diameter of each second recess 235 is less than a width or a diameter of the first recess 231. Further, the width or the diameter of each second recess 235 is less than a width of the line opening 229, and less than a width or a diameter of the via opening 225. Further, a ratio of a sum of opening areas of the second recesses 235 to an opening area of the first recess 231 is less than 1%.

The configuration and the arrangements of the second recesses 235 may be similar to those described above and as shown in FIGS. 12A to 12E; therefore, repeated descriptions are omitted for brevity.

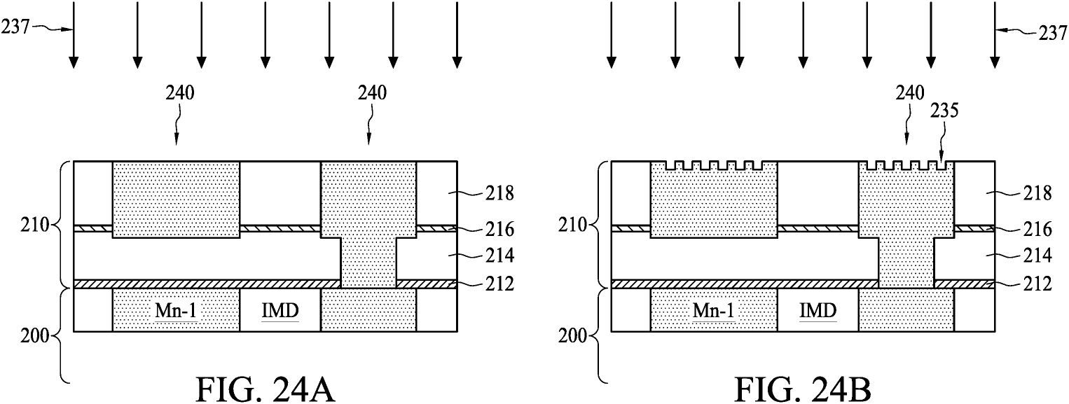

In operation 15, a portion of the conductive material 230 is removed to form a conductive feature 240. Referring to FIGS. 24A and 24B, in some embodiments, the removal is performed by a planarization operation such as a second CMP operation 237. As mentioned above, when there is no second recess formed in the conductive material 230 within the first recess 231, portions of the conductive material 230 suffer from the dishing issue during the CMP operation due to the large polishing area. In contrast to the comparative approaches, the second recesses 235 help reduce a polishing surface of the conductive material within the first recess 231 during the second CMP operation 237. Accordingly, the dishing issue is mitigated.

In some embodiments, the second recesses 235 are entirely removed by the second CMP operation 237, as shown in FIG. 24A. In some embodiments, the second recesses 235 may remain in the conductive feature 240 after the second CMP operation 237. but the depth of the second recesses 235 are reduced by the second CMP operation 237, as shown in FIG. 24B.

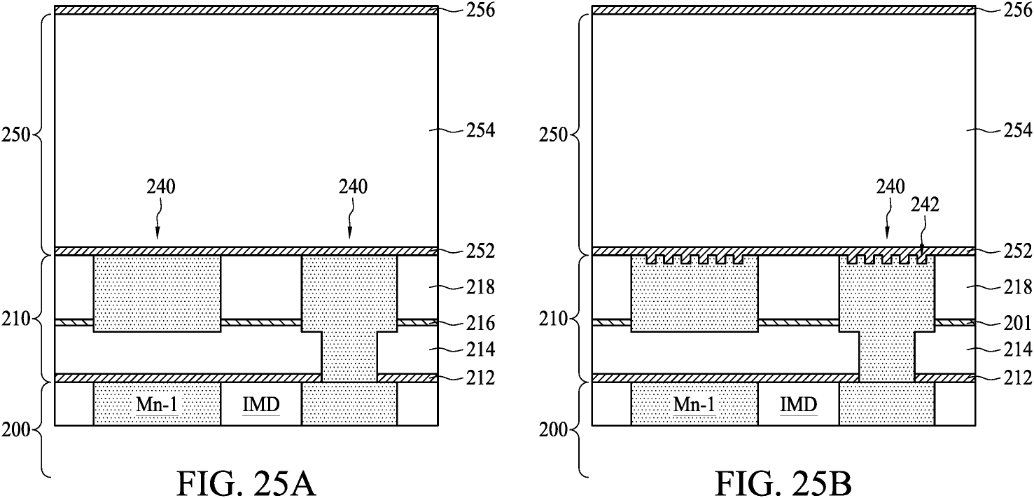

As mentioned above, the conductive feature 240 is used to serve as a metal layer (i.e., the topmost metal layer) of an interconnect structure. Therefore, another insulating layer 250 is formed over the substrate 200. In some embodiments, the insulating layer 250 may be a multiple layer including a variety of dielectric material layers. For example, the insulating layer 250 may include an etch stop layer 252 and a dielectric layer 254 stacked over the substrate 200. Further, a hard mask layer 256 is formed over the insulating layer 250, as shown in FIGS. 25A and 25B. The hard mask layer 256 may be a multiple layer or a single layer.

As shown in FIG. 25A, in some embodiments, when the second recesses 235 are entirely removed, the insulating layer 250 (i.e.. the etch stop layer 252) may be directly formed on the flat surface of the conductive feature 240. In other embodiments, when the second recesses 235 remain in the conductive feature 240 as shown in FIG. 24B, the second recesses 235 may be filled with the insulating layer 250 (i.e., the etch stop layer 252). Accordingly, a plurality of insulating structures 242 are formed in the conductive feature 240.

It should be noted that an area ratio of a sum of surface areas of the insulating structures 242 to a surface area of the conductive feature 240 is less than 1%. A thickness of each insulating structure 242 is less than a thickness of the conductive feature 240 (i.e., a portion of the conductive feature 240 in the line opening 229). In some embodiments, the insulating structures 242 may be arranged to form an array pattern. The insulating structures 242 may be randomly arranged, though not shown. In some embodiments, the conductive feature 240 over the first recess 231 may be defined to have a central region and a peripheral region surrounding the central region. In such embodiments, the insulating structures 242 over the first recess 231 may be arranged and defined to a plurality of first features located in the central region and a plurality of second features located in the peripheral region. Further, a structure density of the first features is greater than a structure density of the second features. In some embodiments, the configuration and the arrangement of the insulating structures 242 may be similar to those depicted in FIGS. 12B to 12E; therefore, repeated descriptions are omitted for brevity.

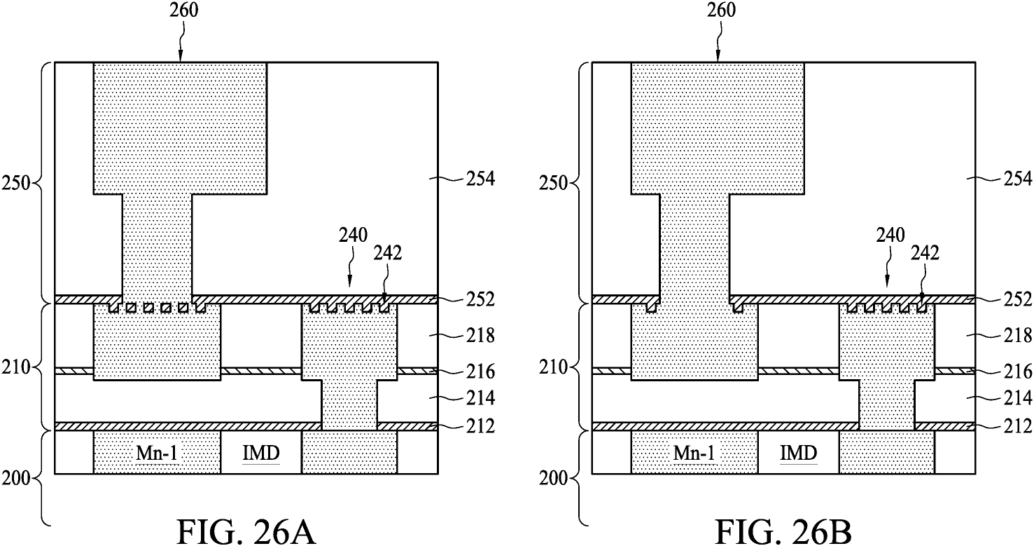

Referring to FIGS. 26A and 26B, in some embodiments, another conductive feature 260 is formed in the insulating layer 250. The conductive feature 260 may be a pad structure, and the pad structure may be formed by the method depicted in FIGS. 2 to 13B; therefore, repeated descriptions are omitted for brevity. In some embodiments, a bottom of the conductive feature 260 may be in contact with top surfaces of some of the insulating structures 242, as shown in FIG. 26A. In such embodiments, a resistance between the conductive feature 240 and the conductive feature 260 may not be influenced by the insulating structures 242 because the area ratio of the sum of the surface areas of the insulating structures 242 to the surface area of the conductive feature 240 is less than 1%. In other embodiments, during the forming of the conductive feature 260. some of the insulating structures 242 are removed and a bottom surface of the conductive feature 260 may be lower than a bottom surface of the remaining insulating structures 242, as shown in FIG. 26B.

According to the method for forming the conductive feature 10, the conductive feature 240, serving as a metal layer of an interconnect structure, is formed with the forming of the second recesses 235 interrupting the first and second CMP operations 232 and 237. The second recesses 235 help reduce a polishing area of the conductive material 230 with in the first recess 231, and thus the dishing issue is mitigated.

In summary, the present disclosure provides a method for forming a conductive feature. In some embodiments, the conductive feature has a pattern formed over its surface. A polishing area may be reduced due to such pattern. Further, the dishing issue may be mitigated due to the reduced polishing area of the connecting structure.

Some embodiments of the present disclosure provide an interconnect structure. The interconnect structure includes a first insulating layer over a substrate, a first conductive feature disposed in the first insulating layer, and a plurality of insulating structures disposed in the first conductive feature. An area ratio of a sum of surface areas of the insulating structures to a surface area of the first conductive feature is less than 1%.

Some embodiments of the present disclosure provide a method for forming a conductive feature. The method includes following operations. A first insulating layer is formed over a substrate. The first insulating layer is patterned to form a first recess in the first insulating layer. The first recess is filled with a conductive material. A plurality of second recesses are formed in the conductive material. Each of the second recesses overlaps the first recess. A portion of the conductive material is removed to form a first conductive feature. A ratio of a sum of opening areas of the second recesses to an opening area of the first recess is less than 1%.

Some embodiments of the present disclosure provide a method for forming a conductive feature. The method includes following operations. An insulating layer is formed over a substrate. A first recess is formed in the insulating layer. A conductive material is formed to fill the first recess. A plurality of second recesses are formed in the conductive material over the first recess. A portion of the conductive material is removed to form a conductive feature. A bonding wire is formed on the conductive feature. A ratio of a sum of opening areas of the second recesses to an opening area of the first recess is less than 1%.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An interconnection structure comprising:
a first insulating layer over a substrate;
a first conductive feature disposed in the insulating layer; and
a plurality of insulating structures disposed in the first conductive feature,
wherein an area ratio of a sum of surface areas of the insulating structures to a surface area of the first conductive feature is less than 1%.

2. The interconnection structure of claim 1, wherein a thickness of the insulating structure is less than a thickness of the first conductive feature.

3. The interconnection structure of claim 1, wherein the insulating structures are randomly disposed in the first conductive feature.

4. The interconnection structure of claim 1, wherein the first conductive feature comprises a central region and a peripheral region surrounding the central region.

5. The interconnection structure of claim 4, wherein the insulating structures further comprise:
a plurality of first features disposed in the central region of the first conductive feature; and
a plurality of second features disposed in the peripheral region of the first conductive feature.

6. The interconnection structure of claim 5, wherein a density of the second features is less than density of the first features.

7. The interconnection structure of claim 1, further comprising:
a second insulating layer over the first insulating layer and the first conductive feature; and
a second conductive feature disposed in the second insulating layer,
wherein the second conductive feature is in contact with the first conductive feature and the insulating structures.

8. The interconnection structure of claim 7, wherein the insulating structures and the second insulating layer comprise a same material.

9. A method for forming a conductive feature, comprising:
forming a first insulating layer over a substrate;
patterning the first insulating layer to form a first recess in the first insulating layer;
filling the first recess with a conductive material;
forming a plurality of second recesses in the conductive material over the first recess,
wherein each of the second recess overlaps the first recess; and
removing a portion of the conductive material to form a first conductive feature, wherein a ratio of a sum of opening areas of the second recesses to an opening area of the first recess is less than 1%.

10. The method of claim 9, further comprising:
performing a first CMP operation prior to the forming of the second recesses; and
performing a second CMP operation after the forming of the second recesses.

11. The method of claim 10, wherein the second recesses are entirely removed by the second CMP operation.

12. The method of claim 10, wherein a depth of each second recess is less than a thickness of the first conductive feature.

13. The method of claim 10, further comprising:
forming a second insulating layer over the first conductive feature; and
forming a second conductive structure in the second insulating layer.

14. The method of claim 13, wherein the second recesses are filled with the second insulating layer to form a plurality of insulating structures.

15. The method of claim 14, wherein the first conductive feature comprises a central region and a peripheral region surrounding the central region.

16. The method of claim 15, wherein the insulating structures further comprises:
a plurality of first features disposed in the central region of the first conductive feature: and
a plurality of second features disposed in the peripheral region of the first conductive feature.

17. The method of claim 16, wherein a density of the second features is less than density of the first features.

18. A method for forming a conductive feature comprising:
forming an insulating layer over a substrate;
forming a first recess in the insulating layer:
filling the first recess with a conductive material;
forming a plurality of second recesses in the conductive material over the first recess;
removing a portion of the conductive material to form the conductive feature; and
forming a bonding wire on the conductive feature,
wherein a ratio of a sum of opening areas of the second recesses to an opening area of the first recess is less than 1%.

19. The method of claim 18, further comprising:
performing a first CMP operation prior to the forming of the second recesses; and
performing a second CMP operation to remove the portion of the conductive material.

20. The method of claim 19, wherein the second recesses are entirely removed by the second CMP operation.
